(19) United States
(12) Patent Application Publication
(10) Pub. No.: US 2008/0206897 A1
(43) Pub. Date: Aug. 28, 2008

(54) Selective Depth Optical Processing

(76) Inventors: Woo Sik Yoo, Palo Alto, CA (US); Kitaek Kang, Dublin, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/679,633

(22) Filed: Feb. 27, 2007

(51) Int. Cl. H01L 21/00

(52) U.S. Cl. 438/7

(57) ABSTRACT

Methods for processing semiconductor materials and substrates with a focused or collimated light beam. Light may be directed on a sample to alter material properties at a depth below the surface. The focused light beam has a peak power density positioned at a selected depth, and absorption of light energy, resulting from selection of wavelength and optical characteristics of the substrate as a function of depth, results in process effects taking place over a preferred limited range of depth. For example, process effects such as curing, annealing, implant activation, selective melting, deposition and chemical reaction may be achieved at dimensions limited by the light beam density in the vicinity of the focused beam spot. The wavelength may be selected to be appropriate for the process effect chosen. The beam may be scanned over the substrate to selectively provide processing effects.

### BACKGROUND

1. Field of Invention

This disclosure generally relates to selective depth processing of semiconductor substrates with a focused light beam.

2. Related Art

Focused laser beams have found applications in drilling, scribing, and cutting of semiconductor wafers, such as silicon. Marking and scribing of non-semiconductor materials, such as printed circuit boards and product labels are additional common applications of focused laser beams. Micro-electromechanical systems (MEMS) devices are laser machined to provide channels, pockets, and through features (holes) with laser spot sizes down to 5 μm and positioning resolution of 1 μm. Channels and pockets allow the device to flex. All such processes rely on a significant rise in the temperature of the material in a region highly localized at the laser beam point of focus.

The foregoing applications, however, are all, to some degree, destructive, and relate generally to focused laser beams at power densities intended to ablate material. In silicon and related semiconductor and electronic materials, such applications are generally for mechanical results (e.g., dicing, drilling, marking, etc.).

Thus, there is a need to provide and control light beams to achieve processing effects for electronic and or optical device fabrication on semiconductor wafers. Furthermore, there is a need to control the depth at which such processing takes place.

### SUMMARY

Methods and systems of semiconductor material and device processing with focused light beams are disclosed. Specifically, in accordance with an embodiment of the disclosure, a method of processing semiconductor materials includes providing a light beam of a selected wavelength and a selected peak power. The laser beam is modulated to provide pulses of a discrete time pulse width. The laser beam is focused at the surface plane of the semiconductor material. The total energy in each laser pulse is controlled to a selected value. By controlling parameters of the light or laser beam, the semiconductor material can be heated or otherwise processed to or at selected depths. The laser beam is scanned over the surface of the semiconductor material in a programmed pattern. Device fabrication is accomplished by altering material electronic and/or optical properties and features at the surface of the semiconductor material.

### BRIEF DESCRIPTION OF THE DRAWINGS

FIGS. 1A and 1B illustrate the effects of light beam density with a longer focal length, in accordance with an embodiment of the disclosure.

FIGS. 2A and 2B illustrate of the effects of light beam density with a shorter focal length, in accordance with an embodiment of the disclosure.

FIGS. 3A and 3B illustrate configurations for selective depth processing in accordance with embodiments of the disclosure.

FIG. 4 is an illustration of an application of selective depth processing in accordance with an embodiment of the disclosure.

Like reference symbols in the various drawings indicate like elements.

### DETAILED DESCRIPTION

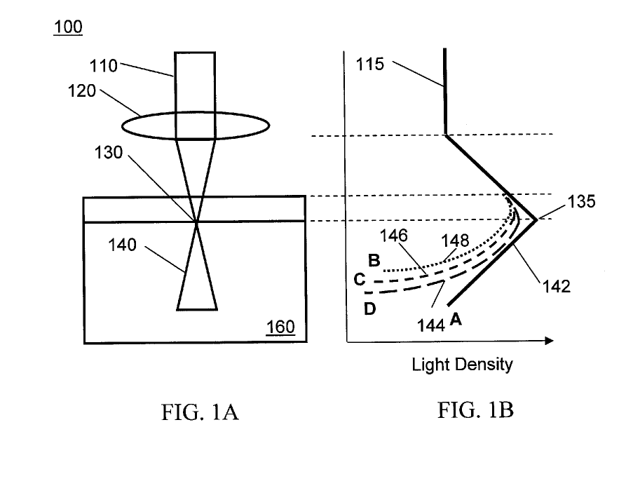

FIGS. 1A and 1B illustrate the effects of light beam density in a selective depth processing system 100 with a longer focal length, in accordance with an embodiment of the disclosure. Referring to FIG. 1A, a collimated light beam 110 is focused by a lens 120 at a selected depth 130 below the surface of a substrate 160. The beam density reaches substantially maximum value at this depth. The beam becomes a divergent beam 140 beyond this point, and the beam density correspondingly decreases.

In FIG. 1B, the light density of the beam is shown as a function of its location in relation to the lens and substrate. As seen in this example, the collimated beam has a constant aperture and light density 115 up to lens 120. Lens 120 may be representative of a single lens or a system of lenses. Lens 120 focuses the beam at selected depth 130 of substrate 160, and the corresponding light density reaches a maximum density 135 at selected depth 130.

Four examples of light propagation conditions may be considered to illustrate the results of light propagation and processing effects in substrate 160. Case A illustrates the dependence of light beam energy density as a function of propagation depth into substrate 160 when substrate 160 is substantially transparent, i.e., there is substantially no light absorption. The dependence of light density 142 on depth is strictly determined by spatial dispersion of divergent beam 140 due to the focal properties of lens 120 and the index of refraction (being substantially real and positive, i.e., without absorption) of substrate 160, and all layers therein. As the substrate material is transparent and non-absorbing, there is substantially no thermal heating and no optical interaction between the beam and substrate 160 to cause any process effects to occur.

Case B illustrates the dependence of light beam energy density as a function of propagation depth into substrate 160 when the substrate material is highly absorptive. This may occur as a result of a combination of layers of the substrate having a complex index of refraction (i.e., having a real and an imaginary component) at the selected wavelength of light beam 110, such that the wavelength dependent index of refraction is complex, which may also occur for a wavelength that is shorter than for cases described below. Those of ordinary skill in the art will recognize that a larger imaginary component of index of refraction will result in a larger rate of absorption. In this case, the light energy is rapidly absorbed by the substrate in a relatively short depth of penetration. Therefore, light beam density 148 of divergent beam 140 decreases rapidly with penetration depth, and processing effects due to thermal heating resulting from the absorption will occur preferentially in a short range of penetration, substantially near the depth corresponding to the focal point 130.

Case C illustrates the dependence of light beam density 146 as a function of propagation depth into substrate 160 when the substrate material has medium absorption, as a result of wavelength selection, which may be a somewhat longer wavelength than in Case B. In this case, light beam density 146 decreases more gradually with penetration depth, and correspondingly penetrates deeper into substrate 160. Therefore, two effects may occur: (1) since absorption is somewhat less than in Case B, heating effects may occur more slowly, and therefore more processing time may be required; (2) since the light density decreases more slowly, the energy density remains relatively high to a greater depth, so that processing effects may occur deeper into substrate 160.

Case D illustrates the dependence of light beam density 144 as a function of propagation depth into substrate 160 when layers of substrate 160 have relatively low absorption, which may also occur at relatively longer wavelengths than in Cases B and C. In this case, light density 144 decreases more gradually and penetrates more deeply into substrate 160.

Because absorption effects are known to typically obey an exponentially decaying dependence with propagation distance, Cases B, C and D are shown with a rate of decreasing light density that is always greater than the decrease due purely to spatial dispersion of the beam due to focal properties in the absence of absorption.

It is well known to those of ordinary skill in the art that an optical system of a given aperture and with a longer focal length will have a larger diffraction limited spot size at the focal point than will an optical system of the same aperture and shorter focal length. This will limit the light beam power and energy density at the focal point to a lower density relative to shorter focal length systems. Thus, a shorter focal length system of the same aperture will have a higher focal point maximum beam power and energy density. In addition, shorter focal point optical systems will also have a more divergent beam, such that the range of depth may be more restricted at which thermally or optically induced processing effects may take place.

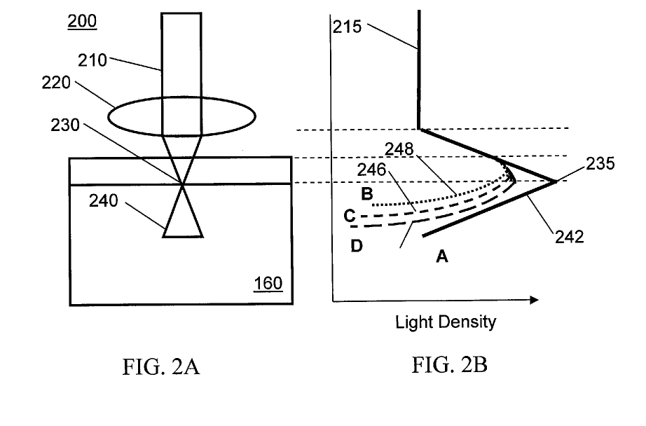

FIGS. 2A and 2B illustrate the effects of light density with a shorter focal length, than the embodiment of FIGS. 1A and 1B in accordance with an embodiment of the disclosure. FIG. 2A contains the same features and elements as in FIG. 1A, except that lens 220 has a shorter focal length than lens 120, such that light beam 210, which is substantially the same as light beam 110, converges to a diffraction limited focal point 230 in a shorter distance, and becomes a more divergent beam 240. Furthermore, the diffraction limited spot size is typically smaller as the focal length is made shorter for the same aperture, which is defined here by light beams 110 and 210. It may therefore be appreciated, as seen from FIGS. 2A and 2B, that light beam density 215, which is substantially the same as light beam density 115, will be focused to focal point 230 and have a correspondingly higher light beam density 235 at this point. Furthermore, as a result of the shorter focal length, beyond the focal point 230, more divergent beam 240 will also result in light density decreasing more rapidly with depth, so that, in all Cases A, B, C and D, light density 242, 248, 244 and 246, respectively, will decrease rapidly in a shorter penetration depth. Therefore, in these cases, processing effects are further limited to a narrower range of depth as compared to the examples of FIGS. 1A and 1B.

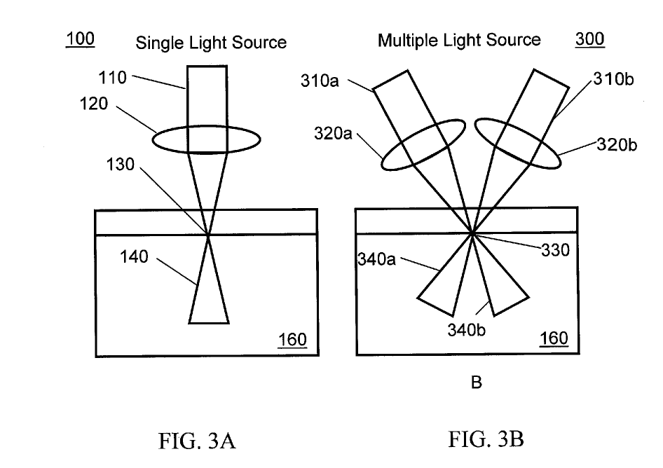

FIGS. 3A and 3B illustrate two embodiments for selective depth processing in accordance with the disclosure. FIG. 3A illustrates a configuration “A” that is substantially identical to that shown in FIG. 1A. FIG. 3B illustrates a configuration including more than one light source to provide multiple light beams. For example, light beams 310a and 310b, provided from a plurality of sources are focused, respectively, by lenses 320a and 320b to provide diffraction limited spots at a common focal point 330 at a selected depth in substrate 160 or alternatively, at different respective focal points (both not shown) at different depths and/or locations in substrate 160. Each lens 320a or 320b may be a single element lens or a representation of a lens system to achieve the same objectives.

Beams 310a and 310b may each be provided by an incoherent light source of selected wavelength and sufficient intensity for a selected application, by lasers of selected intensity and wavelength, or a combination of incoherent light sources and lasers. A greater plurality than is shown in FIG. 3B of light sources of both types may be included.

If the aperture (e.g., diameter) of a light beam, particularly a collimated laser beam, is sufficiently small and the intensity is sufficient for the application, lens 320 may be optionally omitted.

Beams 310a and 310b may have the same wavelength or have different wavelengths. Additionally, beams 310a and 310b may have the same or different apertures (i.e., diameters), which may result in different diffraction limited spot sizes at focal point 330. Beams 310a and 310b may have the same or different total powers. Beams 310a and 310b may be delivered to the substrate by means of mechanical translation of the optical system over substrate 160, galvano-mirror direction of each beam over substrate 160, by translation/rotation of substrate 160 on a processing stage, or a combination of the above.

The range of wavelengths may be from approximately 200 nanometers (i.e., ultraviolet) to approximately 12 micrometers (i.e., long wavelength infrared). Light sources may be sufficiently intense incoherent sources or highly monochromatic lasers. As indicated above, focusing is optional, as the application may require. The optical power obtained from the light sources for selective depth processing may range from approximately 1 milliwatt to 100 kilowatts for continuous (CW) light sources. Alternatively, pulsed light sources may be used, where the per-pulse energy may range from approximately 1 microjoule to approximately 1 joule.

The various combinations of light source, wavelength, focal length and beam combining at or just below the substrate surface provides for a variety of possible applications. Exemplary applications may include local heating or selective depth heating for material processing such as defect engineering or annealing, curing, stress or strain engineering or annealing, local activation, and localized reactions. Multiple light beams of different wavelengths, power levels, focal point depth/location may provide multiple types of processing effects at different depths simultaneously. Note that although the light density is maximum at the desired focal point depth/location, processing can still occur at depths less than and greater than the focal point, but just at less power and over a wider area.

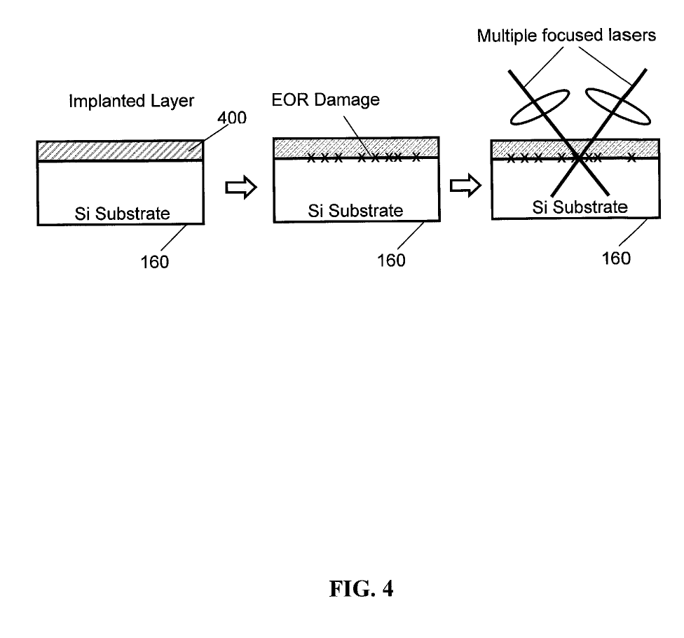

FIG. 4 illustrates an exemplary application of selective depth processing in accordance with an embodiment of the disclosure. Silicon substrate 160 may have received an implanted layer 400 in a prior processing step, where ions of a desired element are electrostatically accelerated to a high energy. The ions impinge on a target substrate and become implanted at a range of depth that depends on the mean and spread of the ion kinetic energy. Each individual ion produces many point defects in the target crystal on impact such as vacancies, interstitials, and crystal dislocations. Vacancies are crystal lattice points unoccupied by an atom. In this case, the ion collides with a target atom, resulting in transfer of a significant amount of energy to the target atom such that it leaves its crystal site. This target atom then itself becomes a projectile in the solid and can cause further successive collision events. Interstitials result when such atoms (or the original ion itself) come to rest in the solid, but find no vacant space in the lattice to reside. These point defects can migrate and cluster with each other, resulting in dislocations and other defects.

Because ion implantation causes damage to the crystal structure of the target which is often unwanted, ion implantation processing is often followed by a thermal annealing. This can be referred to as damage recovery. Furthermore, because this damage—referred to as end of range (EOR) damage—tends to occur over a range of depth determined by the residual kinetic energy of the implant ion as it slows, such that nuclear collision scattering increases, producing an imbedded layer at a depth below the substrate surface that is damaged or at least partially amorphous. Selective depth optical processing applied for thermal annealing may be a highly effective method of removing such defects. One or more light beams, such as two or more laser beams, may be focused to provide localized thermal annealing effectively at the site depths where such defects predominantly accumulate.

In another application, dopant diffusion may be selectively controlled both as to depth and through controlled spatial scanning of the light beam or beams over the substrate area. In another application, localized activation or chemical reactions may be induced, using the same techniques.

Yet another application may use light sources of the same or different wavelengths, where nonlinear optical effects in the substrate material or layers become significant at sufficiently high light beam intensities. Under these conditions, multiple photon mixing may occur, where two incident photons combine by interacting with the substrate lattice and a photon of sum and/or difference energy is produced, thereby providing photons with depth penetration and/or absorption characteristics not available from the light sources directly.

Also, only those claims which use the word “means” are intended to be interpreted under 35 USC 112, sixth paragraph. Moreover, no limitations from the specification are intended to be read into any claims, unless those limitations are expressly included in the claims. Accordingly, other embodiments are within the scope of the following claims.

What is claimed is:

1. A method of processing semiconductor materials and devices comprising:
providing a plurality of one or more light beams of a selected one or more wavelengths and selected powers;
directing the one or more light beams at a selected depth below the surface plane of a semiconductor substrate material;
scanning the one or more light beams over the surface of the semiconductor substrate; and
altering the semiconductor material at the selected depth.

2. The method of claim 1, wherein the plurality of light beams is a single light beam.

3. The method of claim 1, wherein one or more of the plurality of light beams is a laser beam.

4. The method of claim 1, wherein one or more of the plurality of light beams is an incoherent beam.

5. The method of claim 1, wherein the plurality of light beams is a combination of lasers and incoherent light sources.

6. The method of claim 1, wherein the selected wavelength is approximately between 200 nanometers and 12 micrometers.

7. The method of claim 6, wherein the wavelength is selected to optimize altering the semiconductor material by absorption at a selected depth, wherein the selected depth includes a range of depths.

8. The method of claim 1, wherein the light beam is continuous with a power approximately between 1 milliwatt and 100 kilowatts.

9. The method of claim 1, wherein the light beam is a pulsed beam with a per-pulse energy of approximately between 1 microjoule and 1 joule.

10. The method of claim 1, wherein the directing comprises forming a focused diffraction limited spot of the light beam at the selected depth.

11. The method of claim 1, wherein the altering comprises depth controlled processes selected from the group consisting of localized annealing, implant activation, dopant diffusion control, defect engineering, stress engineering, strain engineering, localized chemical reaction, curing, cleaning, ashing, material removal, and/or material modification.

12. The method of claim 1, wherein the wavelengths of the plurality of light beams is a single wavelength.

13. The method of claim 1, wherein the wavelengths of the plurality of light beams comprise one or more wavelengths.

14. The method of claim 13, wherein the wavelengths are selected to mix nonlinearly to provide photons of sum and/or difference energies to obtain selective processing at depths related to the wavelengths of the provided photons.

15. A method for semiconductor processing, comprising:
providing a semiconductor substrate;
selecting properties of a light beam such that the light beam has maximum light density at a desired depth into the substrate;
directing the light beam toward the substrate; and
processing the substrate at the desired depth.

16. The method of claim 15, further comprising focusing the light beam at the desired depth.

17. The method of claim 16, wherein the focusing is with at least one lens.

18. The method of claim 15, wherein the properties comprise power and wavelength.

19. The method of claim 15, wherein the processing comprises localized annealing, implant activation, dopant diffusion control, defect engineering, stress engineering, strain engineering, localized chemical reaction, curing, cleaning, ashing, material removal, and/or material modification.

20. The method of claim 18, wherein the wavelength is approximately between 200 nanometers and 12 micrometers.

21. The method of claim 18, wherein the light beam is continuous with a power approximately between 1 milliwatt and 100 kilowatts.

22. The method of claim 18, wherein the light beam is a pulsed beam with a per-pulse energy of approximately between 1 microjoule and 1 joule.

23. The method of claim 15, further comprising selecting properties of a second light beam such that the second light beam has maximum light density at a desired depth into the substrate; and
directing the second light beam toward the substrate.

24. The method of claim 23, wherein the two light beams intersect at a common location in the substrate.

25. The method of claim 15, wherein the selecting is based on properties of the substrate, the desired depth, and the type of processing.
